(19) United States
(12) Patent Application Publication
(10) Pub. No.: US 2023/0307887 A1
(43) Pub. Date: Sep. 28, 2023

(54) Laser Calibration And Recalibration Using Integrated Wavemeter

(71) Applicant: Nokia Solutions and Networks Oy, Espoo (FI)

(72) Inventors: Brian Stern, Murray Hill, NJ (US); Mark Earnshaw, Berkeley Heights, NJ (US)

(73) Assignee: Nokia Solutions and Networks Oy, Espoo (FI)

(21) Appl. No.: 17/701,645

(22) Filed: Mar. 22, 2022

(51) Int. Cl. H01S 5/0687; H01S 5/06; H01S 5/026

(52) U.S. Cl. CPC H01S 5/0687; H01S 5/0612; H01S 5/026; H01S 5/0617

(57) ABSTRACT

Apparatus and a method are disclosed for calibrating and tuning a wavelength-tunable semiconductor laser. In an assembly, the wavemeter is integrated with the laser, and plural temperature sensors are coupled to plural, spatially separated functional elements of the wavemeter by thermal conduction. A tuning circuit generates tuning signals for the laser that are responsive to wavemeter output signals and to temperature-indication signals from the plural temperature sensors. Temperature effects on the tuning can be mitigated.

### TECHNICAL FIELD

The present disclosure relates to semiconductor lasers, and more particularly to wavelength measurements for the purpose of wavelength control in tunable semiconductor lasers.

### Art Background

Tunable semiconductor lasers have important applications in fields such as optical communications. Various classes of lasers are useful in this regard. They include vertical cavity surface emitting lasers (VCSELs), VCSELs with micro-electromechanical systems (MEMS) tuning structures, sampled grating distributed Bragg reflector (SG-DBR) lasers, and superstructure grating distributed Bragg reflector (SSG-DBR) lasers, among others.

Lasers of the classes listed above belong to the broader category of monolithic semiconductor lasers. Typically, the semiconductor portion of a tunable, monolithic semiconductor laser will include respective segments that serve as adjustable cavity mirrors, gain sections, cavity phase-control sections, and in some cases, external amplification sections. In some cases, lasers of this kind have very stable cavities that can, for example, support operation in a single longitudinal mode with narrow linewidth. Tunable, monolithic semiconductor lasers can also offer wavelength tuning over a wide range. For example, monolithic tunable lasers for telecommunications applications are readily available that can be tuned from a wavelength of 1520 nm to a wavelength of 1565 nm, i.e., over a tuning range of 45 nm. Even broader tuning ranges are available, using hybrid silicon lasers, for example.

Monolithic semiconductor lasers also offer advantages for integration and packaging. In some examples, the laser may be integrated onto a unifying substrate of a multichip module or other hybrid integrated circuit. In other examples, the laser may be integrated directly onto a silicon or SOI wafer to make a hybrid circuit in which waveguides, photodiodes, and other silicon photonic functionality are fabricated in a silicon device layer or nearby layers. Possible modes of attachment include, without limitation, flip-chip attachment, gluing, edge-coupling, and die bonding followed by wafer-level processing.

In the discussion that follows, we will use the term “integrated assembly” to refer to any assembly in which a semiconductor laser is integrated with additional electro-optical functionality in a device or circuit that includes a unifying substrate. By “electro-optical functionality” in this regard, we mean waveguides and other passive devices taken discretely or as comprised in planar lightwave circuits, as well as active devices such as photodetectors, phase shifters, modulators, and silicon-based electronics. In addition to silicon, materials supporting such functionality may include, without limitation, silicon nitride, lithium niobate, and silicon dioxide.

The term “unifying substrate” as used herein refers to any permanent carrier for both the laser and the additional electro-optical functionality. It thus includes wafers in which devices are fabricated, substrates to which devices are attached directly, and substrates to which devices are attached indirectly through intermediate carriers. In all such cases, a device made part of the assembly through fabrication or direct or indirect attachment is “integrated” as that term is used herein.

Depending on its particular design, multiple voltage or current signals may be required to operate and tune a semiconductor laser. For example, Michael C. Larson et al., “High Performance Widely-Tunable SG-DBR Lasers,” Proc. of SPIE 4995 (2003), describe an SG-DBR laser with five waveguide sections longitudinally integrated on a substrate. The five sections are: a gain section, front and back DBR mirror sections, a phase section, and an amplifier. Output power is controlled by current injection in the gain section and amplifier. Tuning is controlled through refractive index changes that are induced by current injection in mirror and phase sections.

Similarly, R. O'Dowd et al., “Frequency Plan and Wavelength Switching Limits for Widely Tunable Semiconductor Transmitters,” IEEE Journal on Selected Topics in Quantum Electronics 7 (2001) 259, report on a four-section SG-DBR laser in which two mirror sections, a phase section, and a gain section each had a control current.

Likewise, A. Novack et al., “A Silicon Photonic Transceiver and Hybrid Tunable Laser for 64 Gbaud Coherent Communication,” 2018 Optical Fiber Communications Conference and Exposition (OFC)(2018), 1-3, report on a silicon photonic, hybrid Vernier ring laser in which each of two ring resonators is thermally tuned with a controllable heating current.

It will thus be understood that a vector of two or more control parameters, such as injection currents, may be needed for tuning. In such a case, the tuning is a function over the possible values of the vector of control parameters. Because the function is generally nonlinear, and may even be discontinuous, a lookup table is useful for representing the tuning function. The lookup table is digitally recorded in a suitable medium, and through signaling, values are retrieved from it as needed to produce a desired output wavelength from the laser. In some cases, analytic or semi-analytic functions may be available to represent at least part of the tuning function. Our definition of “lookup table” in the following discussion is meant to include such analytic and semi-analytic functions as well as tabulations of discrete values.

The process of generating some or all of the lookup table is referred to here as “calibration”, or as “recalibration” in operations subsequent to an initial calibration. Calibration presents certain difficulties, because for integrated semiconductor lasers, it is time-consuming, and it typically requires expensive equipment such as optical spectrum analyzers or bulk wavemeters. Although the lasers can potentially be calibrated at wafer level during production, recalibration may still be needed when assembling components, or in the field. Moreover, the initial lookup table may have been compiled only for particular values of one or more control parameters, for example for only one value of the gain-section current. If a different output power were later required, or if a new current were required due to aging of the components, a new calibration corresponding to some, or even to all, of the lookup table could be needed.

By way of illustration, O'Dowd et al., cited above, describe a scheme for determining the operating points of the laser that would correspond to two thousand wavelength channels. The timescale for this calibration procedure was on the order of one hour.

Larson et al., cited above, also discuss calibration of an SG-DBR laser. As will be discussed below, Larson et al. further describe an integrated component to provide feedback for controlling the wavelength. The integrated component is a 50-GHz etalon-based wavelength locker controlled by a digital signal processor. Power measurements obtained from the reference photodiode of the wavelength locker are fed back to the amplifier current for power stabilization, and the etalon signal is fed back to the phase section for wavelength control. In addition, a signal provided by dithering the grating currents is used to maintain operation near a local optimum operating point.

The use of an integrated component for wavelength measurement is beneficial because it can increase the reliability of the laser at moderate cost. However, such components can introduce their own challenges. For example, etalon-based devices generally suffer from thermal instability. Moreover, the output from typical etalons is spectrally ambiguous, because the detection signal is periodic in wavelength. For example, a typical etalon for operation in the C band, 1530-1565 nm, has a free spectral range on the order of 100 GHz or about 1 nm. Thus, the laser can be stabilized within a local spectral region, but for larger wavelength drifts, it will generally be necessary to determine the actual wavelength. It is notable in this regard that although thermal drift might detune an individual component by only a few tens of gigahertz or less, compound effects due to drifts in the individual components can in some cases lead to large jumps in the output wavelength. In general, therefore, optical spectrum analyzers and/or wavemeters will still be needed to calibrate the tunable laser in the first instance.

The international patent application by David Bitauld, published as WO2020083626A1, the entirety of which we hereby incorporate herein by reference, is of interest in this regard. Bitauld describes a wavemeter embodied on a monolithic integrated circuit for measuring the wavelength of light emitted by a laser that is also included on the same integrated circuit. The wavemeter uses interferometers for phase measurement, but it is designed to overcome the ambiguity typically encountered in interferometric measurements because of the periodicity in the interferometer signal.

However, wavelength-sensitive elements in an integrated assembly will generally be thermally coupled to the laser, which is a major source of heat. Other active elements may also produce heat. The unifying substrate, for example, may provide a conductive pathway for such thermal communication.

Moreover, on the spatial scale of an integrated assembly, this heating can produce significant thermal gradients, so that the wavemeter is heated non-uniformly, and different wavelength-sensitive elements are heated to different average temperatures.

As a consequence, there are threats to the reliability and accuracy of an integrated wavemeter that extend beyond those encountered when the laser and wavemeter are separately integrated. We expect that this will be true even for an integrated wavemeter like that of Bitauld, which was designed to be insensitive to temperature.

Hence, improved methods of temperature stabilization are still needed, especially for assemblies in which the laser and wavemeter are co-integrated.

### SUMMARY OF THE DISCLOSURE

As explained above, temperature gradients can pose a significant problem because if they are present, it may be invalid to assume a common temperature for different functional elements of the wavemeter. By “functional element” in this regard, we mean any structural element of a wavemeter that is sensitive to wavelength and that has a functional role in producing the wavelength-sensitive output of the wavemeter. In the Bitauld wavemeter, for example, functional elements include Mach-Zehnder interferometers (MZIs). Other examples of possible functional elements include, without limitation, microrings, multimode interferometers, arrayed waveguide gratings (AWGs), ninety-degree hybrids, and photodiodes.

In the present disclosure, we address the challenge of non-uniform heating by including a plurality of temperature sensors, i.e., two or more temperature sensors, in the integrated assembly. The temperature sensors can be used to infer temperatures that vary across the wavemeter layout. Diode junctions, for example, have known uses as temperature sensors. Accordingly, diode junctions are provided here as one non-limiting example that is useful in the present context.

In example embodiments, a wavemeter is co-integrated with a laser. Possible uses for the wavemeter may include any of calibrating the laser, re-calibrating the laser, and stabilizing the laser. In a calibration procedure, for example, the wavemeter would be used to construct a tuning map for the laser, which would be stored in a lookup table.

The meaning of “wavemeter” in the present context is a device for unambiguously measuring the wavelength of narrow-band optical emission from a tunable semiconductor laser over the entire tuning range of the laser. By way of illustration, the tuning range of a typical laser for optical communication in the C band is 20 nm or more.

Accurate wavelength measurements are needed in order to provide an effective tuning map. Data from the temperature sensors makes it possible to correct errors in the raw wavemeter output that are due to unequal temperature distributions across the wavemeter. In that way, the accuracy of the wavelength measurements can be improved.

For some applications, feedback stabilization may be employed. In an illustrative embodiment, for example, a portion of the optical emission from the laser is continually directed to the wavemeter. Responsively, electronic control loops between the wavemeter and the laser are used to adjust the tuning controls of the laser. In such an arrangement, data from the temperature sensors again makes it possible to improve the accuracy of the wavelength measurements that inform the feedback loops.

Accordingly, the content of the present disclosure relates, in a first aspect, to an assembly in which a wavemeter is integrated with a wavelength-tunable semiconductor laser. The wavemeter comprises two or more spatially separated functional elements, such as Mach-Zehnder interferometers (MZIs) or other wavelength-measuring devices. These functional elements are coupled to the temperature sensors by thermal conduction. The wavemeter receives at least some of the light emitted by the laser, and a tuning circuit is arranged to apply wavelength-tuning signals to the laser.

The assembly includes two or more spatially separated temperature sensors, which are configured to produce corresponding temperature-indication signals. The tuning circuit is configured to generate the wavelength-tuning signals responsive to the temperature-indication signals and responsive to signals indicative of optical wavelength measurements from the wavemeter.

In embodiments, the laser, the wavemeter, and the temperature sensors are physically integrated to a semiconductor substrate. In more specific embodiments, at least a portion of the laser, such as the gain medium, is bonded to the semiconductor substrate and the wavemeter functional elements are formed in the semiconductor substrate.

In embodiments, the tuning circuit comprises a control circuit configured to infer, from the temperature-indication signals, the temperatures at or near the wavemeter functional elements corresponding to those signals. In more specific embodiments, the control circuit is configured to generate the wavelength-tuning signals in joint response to the signals indicative of optical wavelength measurements and to the inferred temperatures. In more specific embodiments, the control circuit is configured to retrieve values of control parameters from a lookup table, and to generate the tuning signals from the values retrieved from the lookup table.

In embodiments, each temperature sensor comprises a temperature-sensing diode. In more specific embodiments, both the temperature-sensing diodes and the wavemeter functional elements are monolithically integrated on a silicon or SOI substrate.

In embodiments, there are at least three temperature sensors, and at least two of the wavemeter functional elements are located within a polygon having vertices where the three or more temperature sensors are situated.

In embodiments, the tunable semiconductor laser is a heterogeneously integrated III-V laser. In more specific embodiments, the laser is an InP-on-SOI heterogeneous laser, and the laser comprises a silicon waveguide monolithically integrated on the silicon or SOI substrate.

In a second aspect, the content of the present disclosure relates to a control method for the wavelength-tunable semiconductor laser. The disclosed method comprises operations of directing at least some optical emission from the laser into the wavemeter, obtaining a raw wavelength-indicative signal Λ_{raw} from the wavemeter, and computing a temperature-corrected wavelength-indicative signal Λ_{TC}. Notably, the raw wavelength-indicative signal Λ_{raw} may be a vector-valued or multichannel signal, i.e., a signal consisting of outputs from more than one sensor.

The computing of Λ_{TC} comprises obtaining temperature-indicative signals from the spatially separated temperature sensors, computing respective temperatures of two or more spatially separated wavemeter functional elements from the temperature-indicative signals, and computing corrections to Λ_{raw} from the respective temperatures of the spatially separated functional elements.

In embodiments, there are further operations of varying a vector that comprises one or more operating parameters of the laser, computing a temperature-corrected wavelength-indicative signal Λ_{TC} for each of a plurality of values of the operating parameter vector, and recording data indicative of a relation between the operating parameter vector values and temperature-corrected wavelength values derived from Λ_{TC}.

In more specific embodiments, the recording of data is carried out so as to compile a lookup table of wavelength-tuning control values for the laser, or it is carried out so as to modify a pre-existing lookup table of wavelength-tuning control values for the laser.

In embodiments, a signal derived from the temperature-corrected wavelength-indicative signal Λ_{TC} is fed back, in a feedback loop, for stabilizing an emission wavelength of the laser. In embodiments, the raw wavelength-indicative signal Λ_{raw} comprises phase-indicative signals from each of one or more Mach-Zehnder interferometers (MZIs). The raw wavelength-indicative signal Λ_{raw} may be obtained, for example, from a wavemeter comprising four Mach-Zehnder interferometers.

In more specific embodiments, the computing of Λ_{TC} comprises computing a relative frequency from the output of each of the one or more MZIs and computing a free spectral range (FSR) for each of the one or more MZIs, wherein each of said relative frequency and FSR computations takes into account a local temperature obtained from the temperature sensors.

### BRIEF DESCRIPTION OF THE DRAWINGS

FIG. 1 is a simplified depiction of a tuning map for a hybrid silicon laser of the prior art.

FIG. 2 is a simplified block diagram of an example system in which a laser and a wavemeter are co-integrated on a silicon photonic chip.

FIG. 3 is a schematic diagram of a wavemeter that, in accordance with our new approach, has been modified to mitigate the problem of nonuniform heating by adding an arrangement of temperature sensors.

FIG. 3B is a simplified version of FIG. 3A, showing an arrangement of temperature sensors alternative to that of the preceding figure.

FIG. 4 is a sketch showing, in an example, a triangular arrangement of temperature sensors for use in accordance with the principles described here.

FIGS. 5A and 5B are flowcharts of steps that may be used in an example procedure for refining the result of a wavemeter measurement by including local temperature measurements.

FIG. 6 is a notional sketch, in cross section, of a processed wafer including a laser, wavemeter, and temperature sensors according to example embodiments.

FIG. 7 is a functional block diagram showing a system configured to calibrate a laser according to principles described here.

FIG. 8 is a functional block diagram showing a system configured for feedback stabilization of a laser according to principles described here.

### DETAILED DESCRIPTION

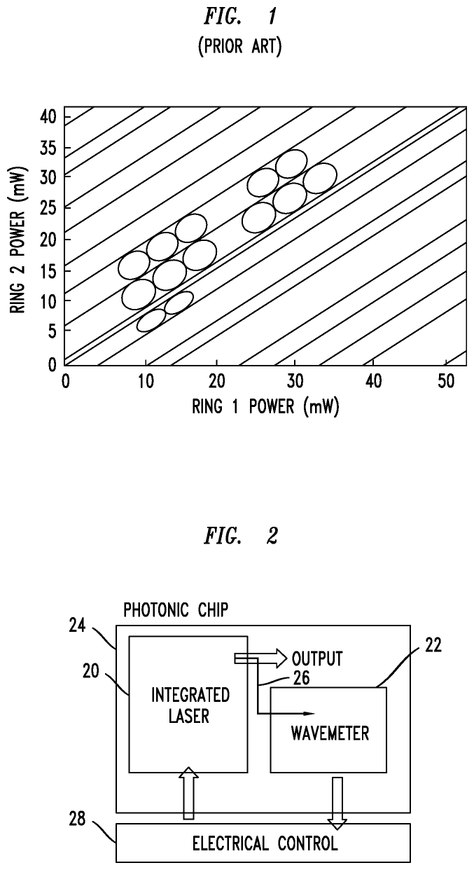

The calibration of an integrated laser typically involves constructing a multidimensional tuning map in which each dimension is based on one of several tuning-control variables. For a hybrid silicon laser, for example, the tuning controls can include heating currents for each of two microring resonators, as well as control currents or control voltages for a phase tuner and for a gain stage. By way of illustration, FIG. 1 is a simplified depiction of a tuning map for a hybrid silicon laser. The figure is adapted from A. Novack et al., cited above, but it has been highly simplified for pedagogical purposes and should be understood as notional only.

Turning to FIG. 1, it will be seen that only two control variables are represented, namely the power levels for the heating currents to the respective microring resonators, denoted “Ring 1” and “Ring 2”. Each of the diagonal bands in the figure is labeled with a respective wavelength value, in nanometers. A few of the stable modal regions, or “mesas,” of the laser are indicated by outlines (idealized here as ellipses) superimposed on the figure. A mode hop occurs when the operating point of the laser crosses an edge of a mesa. For applications in optical telecommunications, it is advantageous for the stable centers of the mesas to correspond to standard WDM channels, such as wavelengths of the 100-GHz ITU grid.

As explained above, there are advantages to using an on-chip wavemeter instead of an optical spectrum analyzer or a bulk wavemeter. Such a wavemeter can be used to calibrate the co-integrated laser, and it can also be used to recalibrate the laser's tuning controls to counteract short-term or long-term drift. For at least some applications, the wavemeter could also possibly be used for feedback stabilization of the laser output wavelength.

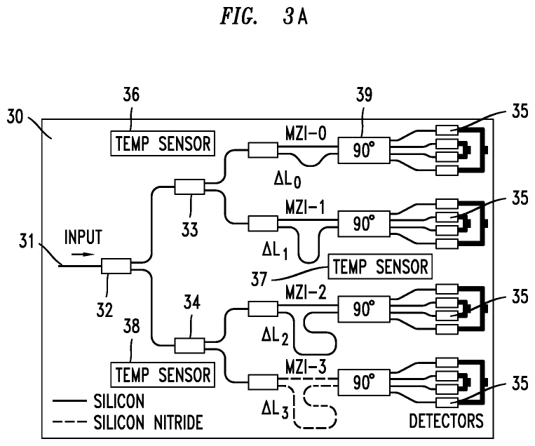

FIG. 2 is a simplified block diagram of an example system in which the laser 20 and the wavemeter 22 are co-integrated on a silicon photonic chip 24. A power tap 26 from the laser directs a portion of the laser output to the wavemeter, which measures the wavelength. Electrical and logical circuitry in control block 28 oversees a control loop. The control loop automatically tunes the laser while constructing a tuning map by varying the tuning controls while measuring the wavelength output. In one useful approach, the tuning map is constructed by detecting the edges of mesas where mode hops occur, and assigning wavelengths to the values in the stable center of each mesa region.

Other approaches may proceed in converse fashion, by first detecting the stable wavelengths.

Subsequent to the initial calibration, it may be necessary to perform stabilization and recalibration due, for example, to aging effects on the laser. With the benefit of an integrated wavemeter, these operations may even be performed in the field. In one useful approach, the wavemeter measures deviations from the setpoint of the laser. The control circuitry adjusts the laser to stay near the set point. This is done by calculating the local gradients of the tuning values and applying the proper adjustments.

For larger drifts, the wavemeter would be able to detect, without spectral ambiguity, the true output wavelength for a given combination of tuning controls. The wavemeter would thus be able to recalibrate the laser within a region of adjacent mesas so as to recenter the setpoint, i.e., so as to realign the relation between the wavelength and the tuning controls.

A complicating factor for the calibration of the laser and for its long-term stability under aging is that there is coupling among the tuning controls, including the output-power adjustment of the gain section. This coupling, which may combine both linear and non-linear effects, makes accurate prediction difficult, and it limits how fast the calibration can be achieved. It is one of the reasons why in-service monitoring and recalibration may be required.

Another complicating factor for the calibration of the laser is heating of the wavemeter, which can lead to measurement error through thermal effects on the refractive index of the wavemeter elements, for example. A principal source of heat is the laser itself. Other sources of heat may include resistive heaters for tuning, and other active components.

As mentioned above, an integrated wavemeter can be designed to be insensitive to temperature, as reported, for example, by Bitauld, cited above. Such a design is referred to here as “athermal”. However, even when an athermal design is used, there is an implicit assumption that the respective functional elements of the wavemeter, such as the interferometers in illustrative embodiments, are all at the same temperature. This assumption can fail if, for example, close integration between the wavemeter and the laser subjects the wavemeter to strong temperature gradients.

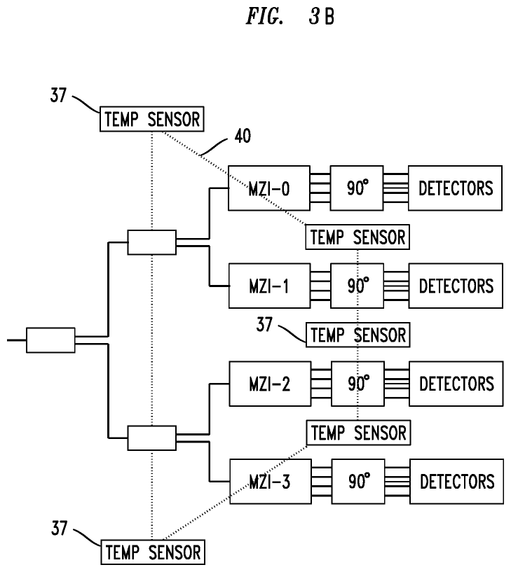

FIG. 3A is a schematic diagram of an athermal wavemeter that, in accordance with our new approach, has been modified to mitigate the problem of nonuniform heating. Portions of the diagram have been adapted from B. Stern et al., “Athermal silicon photonic wavemeter for broadband and high-accuracy wavelength measurements,” Optics Express 29, (13 Sep. 2021) 29946, the entirety of which we hereby incorporate herein by reference.

As shown in the figure, an optical layout is realized on a silicon photonic substrate 30 such as a silicon or SOI wafer. Optical emission from the laser, which is not shown in the figure, is coupled into input waveguide 31. The laser may be integrated on the same wafer, or it may reside on a separate wafer. In the case of separate wafers, the laser wafer and the silicon photonic wafer may be jointly mounted in close proximity to each other on a third, unifying, substrate, with an optical coupling element such as a lens situated between them. It should be understood that these are merely illustrative examples, and that they should not be taken as limiting the scope of the present invention.

The wavemeter of FIG. 3A is based on four Mach-Zehnder interferometers (MZIs), respectively labeled MZI-0, MZI-1, MZI-2, and MZI-3, which are discussed in detail below. Each of the four MZIs constitutes a functional element of the wavemeter. It should be understood that FIG. 3A provides only one illustrative example of a wavemeter, and that various alternative kinds of wavemeters are known in the art and may be useful in the present context. Accordingly, the example of FIG. 3A should not be taken as limiting the scope of the present invention.

Turning to the layout shown in FIG. 3A, it will be seen that splitter 32 divides the input light onto on upper path and a lower path. On the upper path, splitter 33 directs half the light to MZI-0 and half the light to MZI-1. On the lower path, splitter 34 directs half the light to MZI-2 and half the light to MZI-3. Each MZI splits its input into two arms of unequal lengths that differ by a respective geometrical delay length ΔL₀, ΔL₁, ΔL₂, ΔL₃. The two arms of each MZI connect to a 90-degree hybrid 39, using a multimode interference (MMI) coupler, to measure the phase difference between them. As shown, each of the four MMI outputs is followed by a photodetector 35. Outputs of balanced photodetector pairs provide respective in-phase and quadrature signals that can be used for phase measurement.

In the example of FIG. 3A, the arms of MZI-0, MZI-1, and MZI-2 are silicon waveguides, and the arms of MZI-3 are silicon nitride waveguides. MZI-3 has a different composition so that it will have a different thermo-optic coefficient (TOC) than the other MZIs, for reasons that will be explained below. In an illustrative example, the delay lengths are selected to give the MZIs, beginning with MZI-0, respective FSRs of 93.7 nm, 10.8 nm, 1.25 nm, and 2.65 nm. With these selections, following a calibration procedure using a frequency sweep from an external laser, MZI-0 can be used to determine the order of MZI-1, and MZI-1 can be used to determine the orders of MZI-2 and MZI-3. Then, the wavelength can be determined unambiguously from the phase signals provided by MZI-2 and MZI-3. A calibration step with a temperature sweep provides thermal coefficients for the MZIs. With the benefit of these thermal coefficients, temperature dependence can be cancelled from the final wavelength calculation, thus providing an athermal or nearly athermal result.

Turning again to FIG. 3A, it will be seen that three temperature sensors 36, 37, 38 are also situated on the silicon photonic wafer. These temperature sensors are a new feature that is not disclosed in B. Stern et al. More generally, any number of temperature sensors, at least two, may be useful in this regard. By placing these temperature sensors in or near the region of the wavemeter functional elements, temperatures of individual functional elements may be estimated. For example, sensors may be placed between functional elements or within a polygon whose vertices are defined by three or more functional elements. One or more sensors may even be placed outside of such a polygon, provided that care is taken to avoid nearby heat sources that could bias the resulting estimate. As few as two sensors may be useful in this regard, because even though a polygon cannot be formed, a temperature gradient can still be estimated, based on a linear trend.

Any of various kinds of temperature sensors may be used. Diodes, implemented as pn junctions in a silicon substrate layer, may be especially useful in this regard. For a given constant current, the junction voltage is a function of temperature, thus providing a convenient temperature-indicative signal. Alternatives may include, for example, resistive temperature sensors. Suitable resistive films could be deposited, for example, above a silicon device layer but near enough to it for thermal coupling.

By way of example, Po Dong et al., “Reconfigurable 100 Gb/s Silicon Photonic Network-on-Chip [Invited], J. Opt. Commun. Netw. 7 (January 2015) A37, report on a microring modulator implemented in a silicon photonic integrated circuit. Diodes are placed near individual ring devices to sense the local temperatures. We hereby incorporate the entirety of Po Dong et al. herein by reference.

In another example, Christopher T. DeRose et al, “Silicon Microring Modulator with Integrated Heater and Temperature Sensor for Thermal Control,” Conference on Lasers and Electro-Optics 2010 (16-21 May 2010) OSA Technical Digest, paper CThJ3, also report on a silicon microring resonator with an integrated, diode-based temperature sensor. The pn junction for the temperature sensor was defined directly in the region of the microring with n-type doping by ion implantation of arsenic. We hereby incorporate the entirety of Christopher T. DeRose et al. herein by reference.

FIG. 3B is a simplified version of FIG. 3A, showing an alternative arrangement of temperature sensors. In FIG. 3B, it will be seen that a temperature sensor 37 is placed between every pair of 90-degree hybrids, as may be useful for at least some applications. The arrangement of FIG. 3B is also an example of an arrangement in which there is a temperature sensor at each vertex of a polygon that contains at least a portion of each of the MZIs.

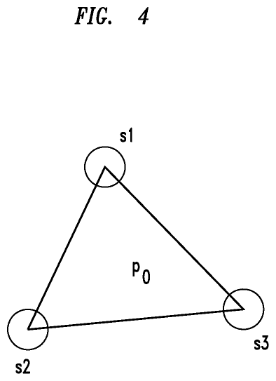

FIG. 4 provides an example of three sensors labeled s1, s2, and s3, arranged in a triangular pattern. In practice, the resulting triangle need not be equilateral. The respective sensor signals are used to estimate the temperature at a point of interest, labeled p in the figure. Although beneficial in some cases, the point p does not necessarily have to lie within the interior of the triangle. The Cartesian coordinates of the point s1 are (s1ₓ, s1_{y}), and similarly for the points s2 and s3. The Cartesian coordinates of the point p are (pₓ, p_{y}).

We will now present an example interpolation formula for estimating the temperature Tₚ at the point p from the temperatures Tₛ₁, Tₛ₂, Tₛ₃ at the respective points s1, s2, and s3. Although we refer to our formula as an interpolation formula, we do not exclude the possibility of using it for extrapolation, i.e., for estimating the temperature at a point exterior to the triangle or other closed polygon defined by the measurement points. It should be understood that the formula to be presented here is only one illustrative example, and it is not meant to exclude other such formulas from the scope of the present invention.

First, we compute the parameters A₁, A₂, A₃, defined by:

$$\begin{matrix}{A}_{1} = \frac{1}{\sqrt{{( s {1}_{x} - {p}_{x} )}^{2} + {( s {1}_{y} - {p}_{y} )}^{2}}} \\ {A}_{2} = \frac{1}{\sqrt{{( s {2}_{x} - {p}_{x} )}^{2} + {( s {2}_{y} - {p}_{y} )}^{2}}} \\ {A}_{3} = \frac{1}{\sqrt{{( s {3}_{x} - {p}_{x} )}^{2} + {( s {3}_{y} - {p}_{y} )}^{2}}}\end{matrix}$$

It will be understood that the denominator of the expression for A₁ is the linear distance between s1 and p, and analogously for A₂ and A₃. Then, Tₚ is calculated from:

$$Tp = \frac{{A}_{1} {T}_{s 1} + {A}_{2} {T}_{s 2} + {A}_{3} {T}_{s 3}}{{A}_{1} + {A}_{2} + {A}_{3}}$$

It will be understood that this expression is a weighted average of the three temperature measurements, in which each weight coefficient is proportional to the inverse distance from p to the respective temperature sensor. The expression can be generalized as a weighted average of measurements from any number of sensors.

For a spatially extensive wavemeter element such as an MZI, a central point may be selected and assumed to provide a good estimate. In a layout such as the one shown in FIG. 3, for example, a temperature for each of the four MZIs can be estimated by performing the above calculation for four points p, each selected to represent a respective one of the MZIs.

Given a temperature estimate for each MZI or other functional element of the wavemeter, these estimates can be used to make a more refined calculation of the measured wavelength. For example, the respective temperatures T₀, . . . , T₃ would replace the common temperature that would conventionally be assumed for the four MZIs of FIG. 3.

Stern et al. provide a detailed description of the computations they use to obtain the laser optical frequency v from the MZI phase measurements made by their athermal wavemeter. The phase measurements are converted to a frequency calculation by a formula that also takes into account a temperature offset ΔT, which is the difference between a temperature T and a reference temperature T_{Ref}; that is, ΔT=T−T_{Ref}. The value of T_{Ref} may be selected, for example, to lie at the midpoint of the temperature calibration range. The calculation uses a set of variables Cᵢ₀, and Cᵢ₂, which are measured thermal calibration coefficients for the respective MZIs, i=0 to 1=3. With our new approach using a plurality of temperature sensors, it is not necessary to use the same value ΔT for all four MZI calculations. Instead, a separate ΔTᵢ=Tᵢ−T_{Ref} can be calculated for each of the respective MZIs.

Below, we will first briefly review the computational procedure described in Stern et al. Then we will explain how our new approach can be used to improve the reliability and accuracy of the measurement.

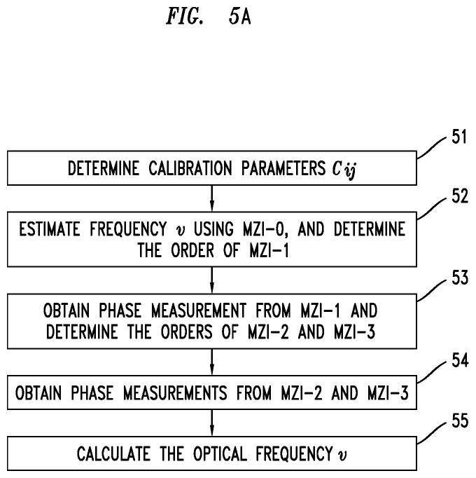

The (uniform temperature) method uses successive calculations, as broadly outlined in FIG. 5A. Once the calibration parameters Cᵢⱼ have been determined (block 51), the procedure first uses MZI-0, which has the largest FSR, to make a first approximation of the optical frequency. This is used to determine (block 52) the interferometer order of MZI-1. The phase measurement of MZI-1 is then used to determine (block 53) the orders of MZI-2 and MZI-3.

Given the known orders of MZI-2 and MZI-3, their phases (obtained at block 54) are used to make a temperature-independent calculation (block 55) of the optical frequency v. If desired, a refined temperature estimate to replace T_{Ref} can be calculated together with the optical frequency v, and the new temperature value (still assumed to be uniform) can be used in a second iteration, which is initiated by returning to block 52. Iterations can continue in that manner until a suitable convergence criterion is met.

More precisely, the procedure involves calculating relative frequencies δv from measured phases, and then using each such frequency approximation to calculate the order of a subsequent MZI. That is:

Each relative phase δ_{φi} is retrieved from the photodetector currents.

Each relative frequency δv₁ is then calculated using

δvᵢ=[δ_{φi}−Cᵢ₀−Cᵢ₁ΔT]/[Cᵢ₂+Cᵢ₁ΔT/ᵥ₀]. [A]

For these first approximations, assuming T=T_{Ref} (i.e., ΔT=0) is sufficient to determine the subsequent MZI orders. For MZI-0, the order is unambiguous, so δv₀ directly refers to the approximate frequency deviation Δv₀ from the beginning of the range at v0.

That is, we use Δv₀=δv₀.

For the subsequent MZI calculations, we use

Δvᵢ=δvᵢ+ΔmᵢFSRᵢ, [B]

where Δmᵢ is the difference between the order mᵢ of MZI-i at v, and the order M_{ref,i} at v₀, i.e., Δmᵢ=mᵢ−m_{ref,i}.

Each FSR is calculated from the calibration parameters by:

FSRᵢ=c[ΔLᵢ(n_{gi}+θᵢΔT)]⁻¹=2π[Cᵢ₂+Cᵢ₁ΔT/v₀]⁻¹. [C]

In the above equation, c is the vacuum velocity of light, and θᵢ is the thermo-optic coefficient (TOC) of the waveguide that constitutes MZI-i.

The order Δmᵢ₊₁ of the next MZI is computed from:

Δmᵢ₊₁=round [(□ΔVᵢ−δvᵢ₊₁)/FSRᵢ₊₁], [D]

We note that in the final step, i=1 determines the orders for both i=2 and i=3, as will be seen below.

We calculate the unknown laser frequency by iteratively applying Equations A-D to each MZI. The first approximation Δv₀ from MZI-0 determines the order of MZI-1. We then compute a second, more accurate approximation of the frequency using Δv₁, which we use to determine the orders of the final two MZIs with

Δm₂₍₃₎=round [(□Δv₁−δv₂₍₃₎) FSR₂₍₃₎]. [E]

With the final two MZI orders known, the relative phases can be related to the phases unwrapped on the calibration range by

Δ_{φ2(3)}=δ_{φ2(3)}+2πΔm₂₍₃₎.

At this point, we can determine the optical input frequency v to the wavemeter using these unwrapped phases measured from the two interferometers with different TOCs, according to:

v=v₀+Δv=v₀+[C₂₁(Δ_{φ3}−C₃₀)−C₃₁(Δ_{φ2}−C₂₀)]·[C₂₁C₃₂−C₃₁C₂₂]⁻¹.

As explained above, our new approach makes it possible to determine a respective temperature offset ΔTᵢ for each of the four MZIs. Accordingly, Equation A and Equation C can be refined by replacing the generic value ΔT with a local value ΔTᵢ for each of the MZIs. In that way, the reliability and accuracy of the wavelength measurement can be improved.

FIG. 5B outlines, in greater detail, an example procedure that uses the local values ΔTᵢ to obtain the frequency calculation of block 55 of the preceding figure. With reference to the figure, the values of the relative phases are obtained from all four MZIs at block 501. The corresponding relative frequencies are calculated at block 502, and the corresponding FSRs are calculated at block 503. It is noteworthy that the local temperatures are invoked both at block 502 and at block 503.

At block 504, the unwrapped frequency offset Δv₀ (i.e., the offset from the beginning v₀ of the measurement range) for MZI-0 is set equal to the relative value δv₀. This is feasible because of the large FSR of MZI-0.

At block 505, the order of MZI-1 is calculated, and at block 506, the corresponding unwrapped frequency offset for MZI-1 is calculated.

At block 507, the unwrapped frequency offset for MZI-1 is used to calculate the orders for MZI-2 and MZI-3, and at block 508, the corresponding unwrapped phases for MZI-2 and MZI-3 are calculated.

At block 509, the frequency v is calculated from the calibration parameters and the unwrapped phases for MZI-2 and MZI-3.

We have shown how local temperature measurements can improve the performance of an athermal wavemeter. Local temperature measurements can also improve the performance of temperature-sensitive wavemeters. In view of what we have provided, particularly Equations A and C, suitable corrections for temperature-sensitive wavemeters will be apparent to those skilled in the art.

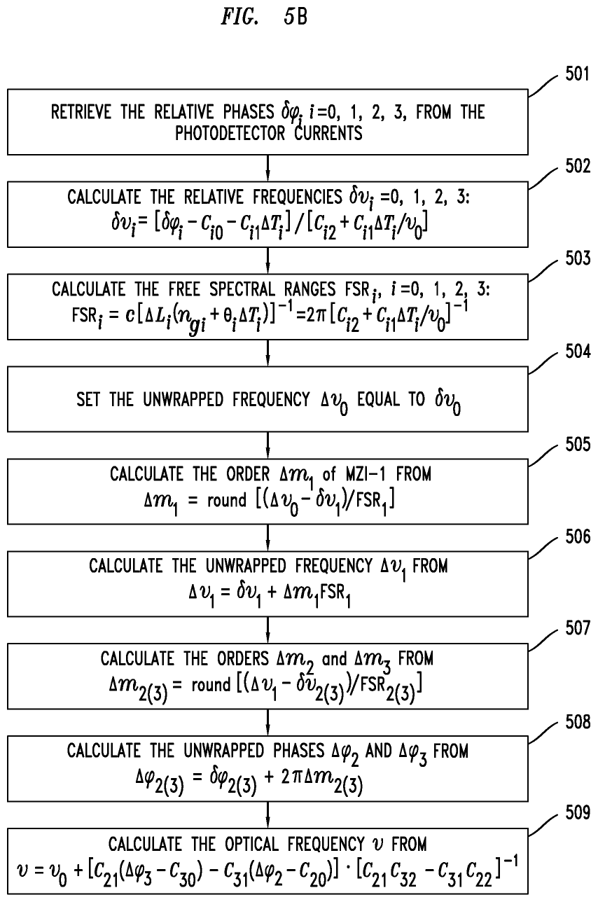

By way of illustration, we provide in FIG. 6 a non-limiting example device according to the principles described here. FIG. 6 is a notional sketch, in cross section, of a processed wafer including a laser, wavemeter, and temperature sensors according to example embodiments in which the laser is bonded to a semiconductor substrate. The figure is not drawn to scale, and it is simplified by the omission of various details that would be known in the art.

Turning to the figure, it will be seen that the wafer includes silicon substrate or substrate layer 60, which includes silicon dioxide cladding 61. Laser 62 in an example embodiment is an InP-on-SOI heterogeneous laser, which includes silicon waveguide 63 embedded in cladding 61. Also embedded in the cladding are silicon MZI waveguides 64, 65 and silicon nitride waveguides 66, 67. Temperature sensors 68, 69 are also shown in the figure, with each constituted by a pn junction. Metal contacts 70, 71 are shown for the laser, metal contacts 72, 73 are shown for temperature sensor 68, and metal contacts 74, 75 are shown for temperature sensor 69.

In a typical implementation, the distance from the laser to the MZIs is on the order of 100 μm, although it could be as short as 20 μm or less, and as long as 2 mm or even more. The individual MZI waveguides in typical implementations are about 0.5 μm wide. A typical separation between the waveguides within an MZI is about 10 μm, although separations as small as 2 μm or less and as large as 100 μm or more are not excluded.

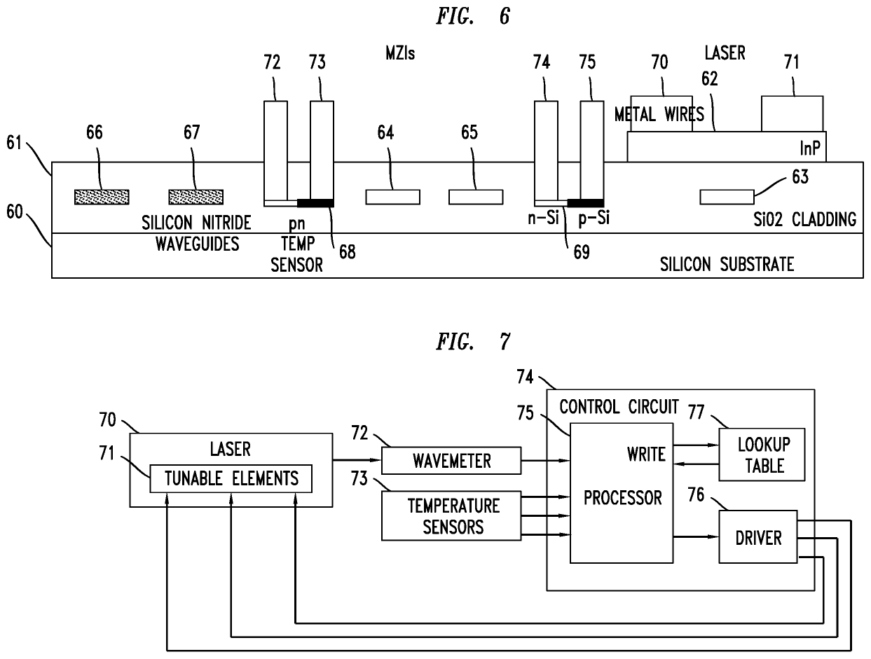

FIG. 7 is a functional block diagram of an example system arranged for calibration or recalibration of a laser according to the principles described above. It is to be understood that FIG. 7 shows only one of many possible arrangements and that as such, it is merely exemplary and non-limiting. Turning to the figure, there will be seen laser 70, including tunable elements 71, optically coupled to wavemeter 72. Temperature sensors 73 are included for determining local temperatures of wavemeter functional elements, as explained above. Control circuit 74 includes a processor 75, a driver 76, and a lookup table 77, which will generally be embodied in a memory device.

The processor may be implemented as a general purpose or special purpose digital computing device. It may also include analog circuitry for various operations that may include, without limitation, signal generation, signal conditioning, modulation, analog-to-digital conversion, digital-to-analog conversion, and the like. Driver 76 generates the control signals for the tunable elements of the laser, under control of the processor. During calibration or re-calibration, the processor stores information in lookup table 77 that relates control values to the output wavelength from the laser, as explained above.

In an example calibration operation, the signals driving the tunable laser elements are varied under control of the processor, temperature-corrected wavelength data is computed by the processor from the wavemeter and temperature-sensor outputs, and the resulting tuning map or similar information is written into the lookup table by the processor, as indicated in the figure.

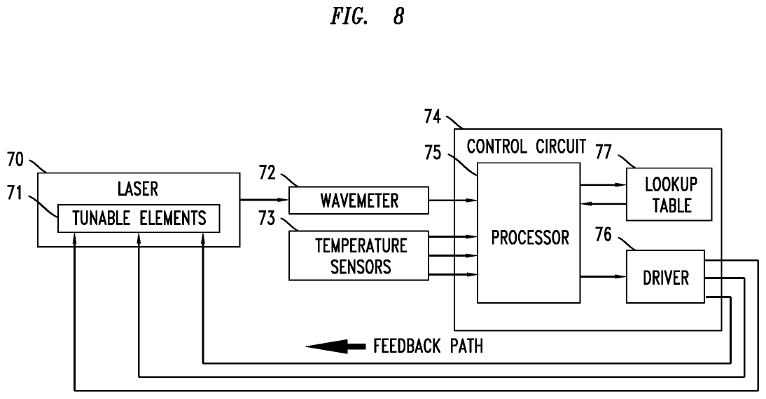

In a different mode of operation, the same or a similar system can be operated for feedback stabilization of the laser. An arrangement for that purpose, in a non-limiting example, is shown in FIG. 8. The use of like reference numerals indicates correspondences between functional blocks shown in FIG. 7 and functional blocks shown in FIG. 8.

Techniques for feedback stabilization of a laser are known. For example, D. Bitauld and B. Stern describe a feedback method using a wavemeter to stabilize a semiconductor laser in European Patent Application No. 20305815.1 of common assignee herewith, titled “Tunable Laser Stabilization” and published on Jan. 19, 2022 under publication number EP3940900A1, the entirety of which is hereby incorporated herein by reference.

Techniques described in the above-cited European Patent Application would be useful in the present context, although we have improved on them by correcting for thermal effects as explained above.

Turning to FIG. 8, it will be seen that there is a feedback path, as indicated by the arrow at the bottom of the figure, from the control circuit to the laser. In the mode of operation that the figure represents, the processor computes the temperature-corrected wavelength deviations from the signals it receives from the wavemeter and from the temperature sensors, and thereby obtains an error signal. In response to the error signal, the processor controls the driver to send corrective tuning signals on the feedback path to the laser.

In some implementations, the processor may retrieve data from the lookup table to use as input for devising the corrective tuning signals. This is indicated in the figure by the bidirectional arrows between the processor and the lookup table.

By way of illustration, the above-cited European Patent Application provides a scheme for stabilizing a laser controlled by three parameters S₁, S₂, and S₃. The sensitivity of the output wavelength λ to these parameters is described by the three local partial derivatives dλ/dS₁, dλ/dS₂, dλ/dS₃, which may be measurable as calibration coefficients and may, e.g., be retrieved from a lookup table. For a measured wavelength deviation dλ0, the respective values (dλ0)/(dλ/dS₁), (dλ0)/(dλ/dS₂), and (dλ0)/(dλ/dS₃) are applied to the appropriate portions of the laser for controlling the output wavelength.

In the present context, our temperature-compensation method may be utilized to refine the measurement of the wavelength deviation and thus to refine the error signal.

We claim:

1. An apparatus, comprising:
at least one wavelength-tunable semiconductor laser and a wavemeter that are optically coupled to each other and physically integrated to a semiconductor substrate, the wavemeter being connected to receive light emitted by the laser;
a tuning circuit to apply wavelength-tuning signals to the laser; and
spatially separated, temperature sensors physically integrated to the substrate and configured to produce corresponding temperature-indication signals, wherein:
the wavemeter comprises two or more spatially separated functional elements coupled to the temperature sensors by thermal conduction; and
the tuning circuit is configured to generate the wavelength-tuning signals responsive to the temperature-indication signals and responsive to signals indicative of optical wavelength measurements from the wavemeter.

2. The apparatus of claim 1, wherein at least a portion of the tunable semiconductor laser is bonded to the semiconductor substrate, and wherein the wavemeter functional elements are formed in the semiconductor substrate.

3. The apparatus of claim 2, wherein the temperature sensors are formed in the semiconductor substrate.

4. The apparatus of claim 1, wherein:
the tuning circuit comprises a control circuit; and
the control circuit is configured to infer temperatures at or near corresponding ones of said functional elements from the plurality of temperature-indication signals.

5. The apparatus of claim 4, wherein the control circuit is further configured to generate the wavelength-tuning signals in joint response to the said signals indicative of optical wavelength measurements and to the said inferred temperatures.

6. The apparatus of claim 5, wherein
the control circuit is configured to retrieve values of control parameters from a lookup table; and
the control circuit is configured to generate the tuning signals from the values retrieved from the lookup table.

7. The apparatus of claim 1, wherein each of the temperature sensors comprises a temperature-sensing diode.

8. The apparatus of claim 1, comprising at least three said temperature sensors, wherein at least two of the wavemeter functional elements are located within a polygon having vertices where the three said temperature sensors are situated.

9. The apparatus of claim 1, wherein:
each of the temperature sensors comprises a temperature sensing diode; and
the wavemeter functional elements and the temperature sensors are monolithically integrated on a silicon or SOI substrate.

10. The apparatus of claim 9, wherein the wavemeter functional elements are Mach-Zehnder interferometers.

11. The apparatus of claim 9 wherein the semiconductor laser is a heterogeneously integrated III-V laser.

12. The apparatus of claim 9, wherein:
the semiconductor laser is an InP-on-SOI heterogeneous laser; and
the laser comprises a silicon waveguide monolithically integrated on the silicon or SOI substrate.

13. A control method for a wavelength-tunable semiconductor laser physically integrated to a semiconductor substrate, comprising:
directing at least some optical emission from the laser into a wavemeter integrated to the semiconductor substrate;
obtaining a raw wavelength-indicative signal Λ_{raw} from the wavemeter; and
computing a temperature-corrected wavelength-indicative signal Λ_{TC},
wherein the computing of Λ_{TC} comprises:
obtaining temperature-indicative signals from a plurality of spatially separated temperature sensors integrated to the substrate;
from the temperature-indicative signals, computing respective temperatures of two or more spatially separated functional elements of the wavemeter; and
computing corrections to Λ_{raw} from the respective temperatures of the spatially separated functional elements.

14. The method of claim 13, wherein:
the method further comprises varying a vector that comprises one or more operating parameters of the laser;
a temperature-corrected wavelength-indicative signal Λ_{TC} is computed for each of a plurality of values of the operating parameter vector; and
the method further comprises recording data indicative of a relation between the operating parameter vector values and temperature-corrected wavelength values derived from Λ_{TC}.

15. The method of claim 14, wherein the recording of data is carried out so as to compile a lookup table of wavelength-tuning control values for the laser.

16. The method of claim 14, wherein the recording of data is carried out so as to modify a pre-existing lookup table of wavelength-tuning control values for the laser.

17. The method of claim 13, further comprising feeding back a signal derived from the temperature-corrected wavelength-indicative signal Λ_{TC} in a feedback loop for stabilizing an emission wavelength of the laser.

18. The method of claim 13, wherein the raw wavelength-indicative signal Λ_{raw} comprises phase-indicative signals from each of one or more Mach-Zehnder interferometers (MZIs).

19. The method of claim 18, wherein the computing of Λ_{TC} comprises computing a relative frequency from the output of each of the one or more MZIs and computing a free spectral range (FSR) for each of the one or more MZIs, wherein each of said relative frequency and FSR computations takes into account a local temperature obtained from the temperature sensors.

20. The method of claim 18, wherein the raw wavelength-indicative signal Λ_{raw} is obtained from a wavemeter comprising four Mach-Zehnder interferometers.
